(19) United States
(12) Patent Application Publication
(10) Pub. No.: US 2025/0016888 A1
(43) Pub. Date: Jan. 9, 2025

(54) APPARATUS FOR PROCESSING SUBSTRATE AND METHOD OF PROCESSING SUBSTRATE

(71) Applicant: SEMES CO., LTD., Cheonan-si (KR)

(72) Inventors: Chae Young LIM, Cheonan-si (KR); Moon Soon CHOI, Asan-si (KR)

(21) Appl. No.: 18/660,317

(22) Filed: May 10, 2024

(30) Foreign Application Priority Data
Jul. 7, 2023 (KR) 10-2023-0088439

(51) Int. Cl. H05B 1/02

(52) U.S. Cl. CPC H05B 1/0244

(57) ABSTRACT

An apparatus for processing a substrate includes a liquid supply line; a pressure tank configured to store liquid; a circulation line including a first heating unit configured to heat liquid, wherein liquid heated by the first heating unit circulates in the pressure tank in a liquid supply standby state, which is before liquid is supplied to the substrate in a process chamber; a pressured gas supply line configured to supply pressured gas to the pressure tank in the liquid supply standby state and to pressurize gas; an exhaust line configured to exhaust gas in the pressure tank; and a control unit configured to control pressure in the pressure tank to increase to a predetermined pressure by opening the pressured gas supply line in a state in which the pressure tank is closed before liquid circulates in the pressure tank in the liquid supply standby state.

### CROSS-REFERENCE TO RELATED APPLICATIONS

The application claims benefit of priority to Korean Patent Application No. 10-2023-0088439 filed Jul. 7, 2023 in the Korean Intellectual Property Office, the disclosure of which is incorporated herein by reference in its entirety.

### BACKGROUND

### 1. Field

Embodiments of the present disclosure relate to an apparatus for processing a substrate and a method of processing a substrate.

To manufacture a semiconductor device or a liquid crystal display, various processes such as photolithography, etching, ashing, ion implantation, and thin film deposition processes are performed on a substrate. Before or after these process are performed, a cleaning process may be performed to clean a substrate to remove contaminants and particles generated in each process.

Generally, a cleaning process may include removing contaminants and particles attached to a substrate by supplying chemical liquid to the substrate. Before liquid is supplied to the substrate in the cleaning process, chemical liquid waiting to be supplied may be continuously heated by being circulated through a tank through a circulation line connected to the tank to maintain a predetermined temperature in a process of preparing high-temperature chemical liquid. The heated chemical liquid may be vaporized in the process of circulating the tank and may evaporate into an exhaust line connected to the tank, such that chemical liquid may be consumed even when the chemical liquid is not supplied, which may be problematic.

### 2. Description of Related Art

An embodiment of the present disclosure is to provide an apparatus for processing a substrate and a method of processing a substrate which may reduce consumption of liquid.

### SUMMARY

According to an embodiment of the present disclosure, an apparatus for processing a substrate includes a liquid supply line configured to supply liquid; a pressure tank disposed on liquid supply line and configured to store liquid; a circulation line including a first heating unit configured to heat liquid disposed therein and connected to the pressure tank, wherein liquid heated by the first heating unit circulates in the pressure tank in a liquid supply standby state, which is before liquid is supplied to the substrate in a process chamber; a pressured gas supply line connected to the pressure tank and configured to supply pressured gas to the pressure tank in the liquid supply standby state and to pressurize gas; an exhaust line connected to the pressure tank and configured to exhaust gas in the pressure tank; and a control unit configured to control pressure in the pressure tank to increase to a predetermined pressure by opening the pressured gas supply line in a state in which the pressure tank is closed by closing the exhaust line before liquid circulates in the pressure tank in the liquid supply standby state.

The liquid supply line may include a main supply line connected to one of the pressure tank and the circulation line and configured to supply liquid from the pressure tank to the substrate in the process chamber, and the control unit controls the exhaust line to open before switching from a liquid supply standby state to a liquid supply state in which liquid is supplied to the substrate in the process chamber through the main supply line.

An exhaust open/close valve and a relief valve may be disposed in the exhaust line.

The main supply line may be connected to the pressure tank, and the apparatus may further include a chamber supply line configured to supply liquid discharged from the pressure tank to the substrate in the process chamber; and a recovery line configured to recover liquid discharged from the pressure tank back to the pressure tank.

The main supply line disposed on an upper side of the chamber supply line and the recovery line may include a second heating unit configured to heat liquid.

The apparatus may further include a pressure measurement unit configured to measure pressure in the pressure tank, wherein the control unit may control an output of the first heating unit to maintain pressure in the pressure tank at a predetermined pressure according to a pressure value measured from the pressure measurement unit.

The pressure tank may include at least a first pressure tank and a second pressure tank, and when one of the first pressure tank and the second pressure tank is in liquid supply state, the other may be controlled to be in the liquid supply standby state.

According to another embodiment of the present disclosure, a method of processing a substrate using a pressure tank disposed on a liquid supply line configured to supply liquid and connected to a circulation line in which liquid stored therein circulates while being heated and an exhaust line includes a liquid supply standby operation in which, by closing the exhaust line, pressured gas is supplied to the sealed pressure tank and is pressurized, and liquid in the pressure tank circulates in the pressure tank while being heated through the circulation line; and a liquid supply operation in which liquid is supplied to a substrate in a process chamber through the pressure tank.

The method may further include a liquid supply preparation operation in which the exhaust line is gradually opened after the liquid supply standby operation and before the liquid supply operation.

An exhaust open/close valve and a relief valve disposed on the exhaust line may be opened in the liquid supply preparation operation, the exhaust open/close valve and the relief valve may be maintained in an open state in the liquid supply operation, and the exhaust open/close valve and the relief valve may be closed in the liquid supply standby operation.

In the liquid supply standby operation, an output of a heating unit configured to heat liquid circulating in the pressure tank may be controlled such that pressure in the pressure tank may be maintained at a predetermined pressure.

According to another embodiment of the present disclosure, a method of processing a substrate using a first pressure tank disposed on a liquid supply line configured to supply liquid and connected to a first circulation line in which liquid stored therein circulates while being heated and a first exhaust line; and a second pressure tank disposed in parallel to the first pressure tank on the supply line and connected to a second circulation line in which liquid stored therein circulates while being heated and a second exhaust line includes a first liquid supply standby operation in which, by closing the first exhaust line, pressured gas is supplied to the sealed first pressure tank and is pressurized, and liquid in the first pressure tank circulates the first pressure tank while being heated through the first circulation line; a second liquid supply standby operation in which, by closing second exhaust line, pressured gas is supplied to the sealed second pressure tank and is pressurized, and liquid in the second pressure tank circulates the second pressure tank while being heated through the second circulation line; a first liquid supply operation in which liquid is supplied to the substrate in the process chamber through the first pressure tank; and a second liquid supply operation in which liquid is supplied to the substrate in the process chamber through the second pressure tank, wherein the first liquid supply operation and the second liquid supply standby operation may be performed simultaneously, and wherein the second liquid supply operation and the first liquid supply standby operation may be performed simultaneously.

The method may further include a first liquid supply preparation operation in which the first exhaust line is gradually opened after the first liquid supply standby operation and before the first liquid supply operation.

A first exhaust open/close valve and a first relief valve disposed on the first exhaust line may be opened in the first liquid supply preparation operation.

In the first liquid supply standby operation, an output of the heating unit configured to heat liquid circulating the first pressure tank may be controlled such that pressure in the first pressure tank may be maintained at a predetermined pressure.

The method may further include a second liquid supply preparation operation in which the second exhaust line is gradually opened after the second liquid supply standby operation and before the second liquid supply operation.

A second exhaust open/close valve and a second relief valve disposed on the second exhaust line may be opened in the second liquid supply preparation operation.

In the second liquid supply standby operation, an output of the heating unit configured to heat liquid circulating the second pressure tank may be controlled such that pressure in the second pressure tank may be maintained at a predetermined pressure.

A portion of the first circulation line and a portion of the second circulation line may be configured as a shared line, and in the first liquid supply standby operation or the second liquid supply standby operation, liquid circulating the first circulation line or the second circulation line may be heated by a heating unit disposed in the shared line.

The method may further includes a first liquid supply preparation operation in which the first exhaust line is gradually opened after the first liquid supply standby operation and before the first liquid supply operation; the method further includes a second liquid supply preparation operation in which the second exhaust line is gradually opened after the second liquid supply standby operation and before the second liquid supply operation, a first exhaust open/close valve and a first relief valve disposed on the first exhaust line are opened in the first liquid supply preparation operation, the first exhaust open/close valve and the first relief valve are maintained in an open state in the first liquid supply operation, and the first exhaust open/close valve and the first relief valve are closed in the first liquid supply standby operation, and the second exhaust open/close valve and the second relief valve disposed on the second exhaust line are opened in the second liquid supply preparation operation, the second exhaust open/close valve and the second relief valve are maintained in an open state in the second liquid supply operation, and the second exhaust open/close valve and the second relief valve are closed in the second liquid supply standby operation.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating an apparatus for processing a substrate according to an embodiment of the present disclosure

FIG. 2 is a flowchart illustrating a method of processing a substrate of an apparatus for processing a substrate according to an embodiment of the present disclosure;

FIG. 3 is a diagram illustrating an apparatus for processing a substrate according to an embodiment of the present disclosure; and

FIG. 4 is a flowchart illustrating a method of processing a substrate of an apparatus for processing a substrate according to an embodiment of the present disclosure;

### DETAILED DESCRIPTION

Hereinafter, embodiments of the present disclosure will be described as below with reference to the attached drawings. Various embodiments will be described with reference to accompanying drawings. However, the may not necessarily limit the scope of the embodiments to a specific embodiment form.

Instead, modifications, equivalents and replacements included in the disclosed concept and technical scope thereof description may be employed. Throughout the specification, similar reference numerals are used for similar elements.

In the embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” The terms, “include,” “comprise,” “is configured to,” or the like of the description are used to indicate the presence of features, numbers, steps, operations, elements, portions or combination thereof, and do not exclude the possibilities of combination or addition of one or more features, numbers, steps, operations, elements, portions or combination thereof.

The terms used in the following description are provided to explain a specific exemplary embodiment and are not intended to be limiting. A singular term may include a plural form unless otherwise indicated. All the terms used herein including technical or scientific terms have the same meanings as those generally understood by an ordinary skilled person in the related art unless they are defined otherwise. The terms defined in a generally used dictionary should be interpreted as having the same meanings as the contextual meanings of the relevant technology and should not be interpreted as having ideal or exaggerated meanings unless they are clearly defined in the various embodiments. In some cases, even the terms defined in the present disclosure may not be interpreted to exclude the embodiments.

In the description below, an apparatus for processing a substrate according to an embodiment will be described with reference to the drawings.

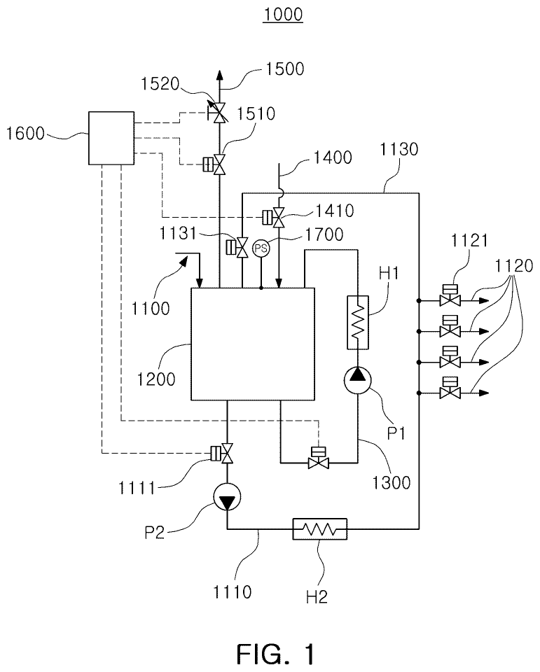

FIG. 1 is a diagram illustrating an apparatus for processing a substrate according to an embodiment.

Referring to FIG. 1, an apparatus for processing a substrate 1000 according to an embodiment may include a liquid supply line 1100, a pressure tank 1200, a circulation line 1300, a pressured gas supply line 1400, an exhaust line 1500 and a control unit 1600.

Liquid supply line 1100 may receive liquid from a liquid supply source and may supply various types of liquid to the substrate in the process chamber such that the substrate may be processed. Liquid supply line 1100 may supply liquid to a substrate in one or a plurality of process chambers, if desired. In FIG. 1, liquid supply line 1100 may supply liquid to the substrate in each process chamber through a plurality of chamber supply line 1120 of a main supply line 1110, which will be described later, but an embodiment thereof is not limited thereto.

Here, in the apparatus for processing a substrate 1000 according to an embodiment, the process chamber may be configured to perform a process on a substrate disposed in the process chamber using processing liquid such as chemical liquid, and a cleaning process of cleaning contaminants on the substrate or an etching process of etching a film formed on the substrate may be performed. However, in the embodiment, the process performed in the process chamber is not limited thereto, and the embodiment may be applied to various processes other than the cleaning process and the etching process in case in which the process is performed for the substrate by supplying liquid to the substrate.

The pressure tank 1200 may be configured to be disposed on liquid supply line 1100 and to store liquid, and if desired, pressured gas may be supplied to the pressure tank 1200 through a pressured gas supply line 1400 to be described later, such that the pressure tank 1200 may store liquid in a state in which an internal portion thereof is pressurized with pressured gas.

The circulation line 1300 may be connected to the pressure tank 1200 such that liquid in the pressure tank 1200 may circulate in the pressure tank 1200 through the circulation line 1300. In the circulation line 1300, a first heating unit H1 configured to heat liquid may be disposed. The circulation line 1300 may allow liquid heated by the first heating unit H1 to circulate in the pressure tank 1200 in a liquid supply standby state. Here, the liquid supply standby state may refer to a state before liquid is supplied to the substrate in the process chamber through the chamber supply line 1120 of the liquid supply line 1100.

Also, the first pump P1 configured to pump liquid in the pressure tank 1200 for liquid to circulate in the pressure tank 1200 through the circulation line 1300 may be disposed in the circulation line 1300.

The pressured gas supply line 1400 may be connected to the pressure tank 1200 and may supply pressured gas to the pressure tank 1200. A pressured gas supply valve 1410 may be disposed on the pressured gas supply line 1400, and whether pressured gas is supplied from the pressured gas supply line 1400 into the pressure tank 1200 through the pressured gas supply valve 1410 and a supply flow rate thereof may be adjusted. As pressured gas, the pressured gas supply line 1400 may supply N₂ gas, for example, into the pressure tank 1200. By supplying N₂ gas into the pressure tank 1200 through the pressured gas supply line 1400, gas may work as a purge to prevent gases or contaminants other than liquid from being accommodated in the pressure tank 1200.

The pressured gas supply line 1400 may supply pressured gas to the pressure tank 1200 in a liquid supply standby state and may pressurize an internal portion of the pressure tank 1200. Specifically, in the liquid supply standby state, when the pressure tank 1200 is in a sealed state, the pressure tank 1200 may supply pressured gas to the pressure tank 1200 through the pressured gas supply line 1400 in a sealed state and may pressurize the internal portion of the pressure tank 1200.

An exhaust line 1500 configured to exhaust gas in the pressure tank 1200 may be connected to the pressure tank 1200. The exhaust line 1500 may be closed in the liquid supply standby state such that the pressure tank 1200 may be in a closed state.

The control unit 1600 may control operations of each component of the apparatus for processing a substrate 1000. Specifically, before liquid circulates in the pressure tank 1200, the control unit 1600 may close the exhaust line 1500 in the liquid supply standby state, may open the pressured gas supply line 1400 in the sealed state of the pressure tank 1200 and may control such that pressure in the pressure tank 1200 increases to a predetermined pressure.

In the apparatus for processing a substrate 1000 having the above configuration, in the liquid supply standby state, as the liquid is heated through the circulation line 1300, the control unit 1600 may control the exhaust line 1500 connected to the pressure tank 1200 to close before circulating the pressure tank 1200 and may control the pressured gas supply line 1400 to open, such that, by supplying pressured gas into the pressure tank 1200, pressure in the pressure tank 1200 may be increased, and as pressure in pressure tank 1200 increases, a boiling point of the liquid in the pressure tank 1200 may increases, thereby preventing evaporation of the liquid, which may reduce vaporization of liquid. Further, since the exhaust line 1500 is in a closed state in the liquid supply standby state, processing gas from liquid vaporized in the sealed pressure tank 1200 may not be discharged to the exhaust line 1500 and may be maintained in the pressure tank 1200, thereby reducing consumption of liquid.

Further, in the liquid supply standby state, before liquid circulates in the pressure tank 1200, for the control unit 1600 to control pressure in the pressure tank 1200 to increase to a predetermined pressure by closing the exhaust line 1500 and opening the pressured gas supply line 1400, the apparatus for processing a substrate 1000 may include a pressure measurement unit 1700 measuring pressure in the pressure tank 1200. The pressure measurement unit 1700 may be disposed in the pressure tank 1200 and may include a pressure sensor.

In this case, the control unit 1600 may control an output of the first heating unit H1 such that pressure in the pressure tank 1200 may be maintained at a predetermined pressure according to a pressure value measured from the pressure measurement unit 1700.

Specifically, in the liquid supply standby state, in the process of circulating liquid through the pressure tank 1200 through the circulation line 1300, by controlling the output of the first heating unit H1 of the circulation line 1300 according to the pressure value measured from the pressure measurement unit 1700, pressure in the pressure tank 1200 may be maintained at a predetermined pressure.

Also, liquid supply line 1100 may include a main supply line 1110 connected to one of the pressure tank 1200 and the circulation line 1300 and supplying liquid from the pressure tank 1200 to the substrate in the process chamber. For example, as illustrated in FIG. 1, the main supply line 1110 may be connected to the pressure tank 1200. The main supply valve 1111, which opens and closes or regulates a flow of liquid from the pressure tank 1200, may be disposed on the main supply line 1110. The main supply line 1110 may include a chamber supply line 1120 and a recovery line 1130. The chamber supply line 1120 may supply liquid discharged from the pressure tank 1200 to the substrate in the process chamber. A plurality of the chamber supply lines 1120 may be provided, and a chamber supply valve 1121 may be disposed on each chamber supply line 1120. The recovery line 1130 may recover liquid discharged from pressure tank 1200 back to the pressure tank 1200. That is, the recovery line 1130 may enable liquid to recover to the pressure tank 1200 without being supplied to the chamber supply line 1120 when pressure of liquid in the main supply line 1110 is above a predetermined pressure. The recovery valve 1131 may be disposed in the recovery line 1130, and whether to recover liquid from the main supply line 1110 to the pressure tank 1200 and a recovery flow rate may be adjusted through the recovery valve 1131 of the recovery line 1130.

Further, a second heating unit H2 for heating liquid and a second pump P2 for pumping liquid in the flow direction of liquid may be included in the main supply line 1110 on an upper side of the chamber supply line 1120 and the recovery line 1130. Accordingly, in the liquid supply standby state, liquid heated by the first heating unit H1 while circulating the pressure tank 1200 through the circulation line 1300 may be, when the state is switched to the liquid supply state, discharged from pressure tank 1200, may be supplied to main supply line 1110, may be secondarily heated by the second heating unit H2 and may be supplied to the substrate in the process chamber through the chamber supply line 1120. In this case, if desired, the control unit 1600 may control the output of the second heating unit H2 of the main supply line 1110 according to the pressure value measured from the pressure measurement unit 1700 in the process of recovering liquid back to the pressure tank 1200 through the recovery line 1130 of the main supply line 1110, such that pressure in the pressure tank 1200 may be maintained at a predetermined pressure.

Also, when switching from the liquid supply standby state to the liquid supply state in which liquid is supplied to the substrate in the process chamber through the chamber supply line 1120 of the main supply line 1110, to reduce the risk of explosion due to high pressure in the pressure tank 1200, the control unit 1600 may control the exhaust line 1500 to be opened before switching from the liquid supply standby state to the liquid supply state. For example, before switching from the liquid supply standby state to the liquid supply state, the control unit 1600 may control the exhaust line 1500 to be gradually open. To implement this, as an example, an exhaust open/close valve 1510 and a relief valve 1520 may be disposed on the exhaust line 1500. By including the components, before switching from the liquid supply standby state to the liquid supply state, the control unit 1600 may control the exhaust open/close valve 1510 and the relief valve 1520 to be open, thereby gradually reducing pressure in the pressure tank 1200 through the exhaust line 1500. Since pressure may be released, explosion due to sudden pressure changes may be effectively prevented when switching from the liquid supply standby state to the liquid supply state.

According to an embodiment, a method of processing a substrate using the apparatus for processing a substrate 1000 may be provided.

Before describing the method of processing a substrate of the embodiment, as for a general method of processing a substrate, as a general method of processing a substrate, in the standby state before supplying the liquid, an exhaust line connected to a tank storing liquid may be circulated while heating liquid in an open state. In this case, when liquid is not supplied for a relatively long period of time, liquid may continuously circulate in the tank and may be continuously heated to maintain a predetermined temperature. Accordingly, the heated liquid may be vaporized and may evaporate into an exhaust line connected to the tank, such that consumption of liquid may increase.

To address the issue, a method of processing a substrate according to an embodiment may be provided as below.

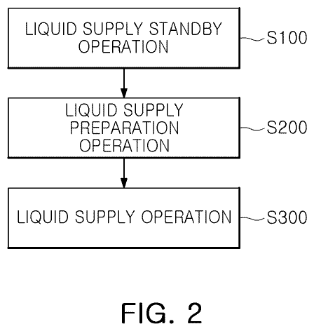

FIG. 2 is a flowchart illustrating a method of processing a substrate of an apparatus for processing a substrate according to an embodiment.

Referring to FIGS. 1 and 2, by using the method of processing a substrate according to an embodiment, liquid may be supplied to the substrate in the process chamber and may be processed using the pressure tank 1200 disposed on the liquid supply line 1100 configured to supply liquid. Specifically, the pressure tank 1200 may be connected to a circulation line 1300 in which liquid stored in the pressure tank 1200 may circulate while being heated and an exhaust line 1500 configured to exhaust gas in the pressure tank 1200. Also, the pressured gas supply line 1400, which supplies pressured gas into the pressure tank 1200, may be connected to the pressure tank 1200 as described above, and the main supply line 1110 of the liquid supply line 1100 may also be connected.

The method of processing a substrate of the apparatus for processing a substrate 1000 may include a liquid supply standby operation (S100) and a liquid supply operation (S300).

In the liquid supply standby operation (S100), pressured gas may be supplied to the sealed pressure tank 1200 by closing the exhaust line 1500 and may be pressurized, and liquid in the pressure tank 1200 may circulate the pressure tank 1200 while being heated through the circulation line 1300. In liquid supply standby operation (S100), pressured gas may be supplied to the pressure tank 1200 by opening the pressured gas supply valve 1410 of the pressured gas supply line 1400 connected to the pressure tank 1200. Also, in the liquid supply standby operation (S100), liquid may be heated by the first heating unit H1 of the circulation line 1300 while circulating the pressure tank 1200 through the circulation line 1300.

In the liquid supply operation (S300), liquid may be supplied to the substrate in the process chamber through the pressure tank 1200. That is, liquid discharged from the pressure tank 1200 in the liquid supply operation (S300) may be supplied to the substrate in the process chamber through the chamber supply line 1120 of the main supply line 1110 and allow the substrate to be processed.

According to the method of processing a substrate, in the liquid supply standby operation (S100) before the liquid supply operation (S300), liquid may be heated through the circulation line 1300, and by closing the exhaust line 1500 connected to the pressure tank 1200 before circulating the pressure tank 1200, pressured gas may be supplied to the sealed pressure tank 1200, such that pressure in the pressure tank 1200 may be increased, and as the pressure in pressure tank 1200 increases, a boiling point of the liquid in pressure tank 1200 may increase, such that evaporation of the liquid may be prevented, which may reduce vaporization of liquid. Further, since the exhaust line 1500 is in a closed state in the liquid supply standby operation (S100), processing gas from liquid vaporized in the sealed pressure tank 1200 may not be discharged to the exhaust line 1500 and may be maintained in the pressure tank 1200, thereby reducing consumption of liquid.

Further, in the liquid supply standby operation (S100), an output of the heating unit for heating liquid circulating in the pressure tank 1200 may be controlled such that pressure in the pressure tank 1200 may be maintained at a predetermined pressure. Here, the heating unit may be the first heating unit H1 described above. Specifically, in the liquid supply standby operation (S100), a pressure value in the pressure tank 1200 may be measured and an output of the first heating unit H1 may be controlled such that pressure in the pressure tank 1200 may be maintained at a predetermined pressure according to the measured pressure value.

Also, when switching from the liquid supply standby operation (S100) to the liquid supply operation (S300), there may be a risk of explosion due to high pressure in the pressure tank 1200, and to prevent this, the method of processing a substrate may further include a liquid supply preparation operation (S200). The liquid supply preparation operation (S200) may be of gradually opening the exhaust line 1500 after the liquid supply standby operation (S100) and before the liquid supply operation (S300).

The method of gradually opening the exhaust line 1500 in the liquid supply preparation operation (S200) may be varied. For example, an exhaust open/close valve 1510 and a relief valve 1520 may be disposed on the exhaust line 1500. Specifically, before switching from the liquid supply standby state to the liquid supply state, the liquid supply preparation operation (S200) may be performed to open the exhaust open/close valve 1510 and the relief valve 1520 disposed on the exhaust line 1500, such that pressure in the pressure tank 1200 may be gradually released through the exhaust line 1500, and accordingly, when performing the liquid supply operation (S300), explosion due to rapid pressure changes in the pressure tank 1200 may be effectively prevented.

Further, when the exhaust open/close valve 1510 and the relief valve 1520 are disposed on the exhaust line 1500, the exhaust open/close valve 1510 and the relief valve 1520 may maintain an open state in the liquid supply operation (S300). Also, in the liquid supply standby operation (S100), the exhaust open/close valve 1510 and the relief valve 1520 may be closed such that the pressure tank 1200 may be in a sealed state.

In the embodiment described above, the exhaust open/close valve 1510 and the relief valve 1520 may be provided as an embodiment for gradually opening the exhaust line, but an embodiment thereof is not limited thereto, and any component for gradually opening the exhaust line may be applied. As another example, a control valve for adjusting an exhaust flow rate of the exhaust line may be provided.

In the above, the apparatus for processing a substrate including a pressure tank and the method of processing a substrate using the same have been described in detail, but the embodiment is not limited thereto and, if desired, an embodiment including a plurality of pressure tank may also be implemented.

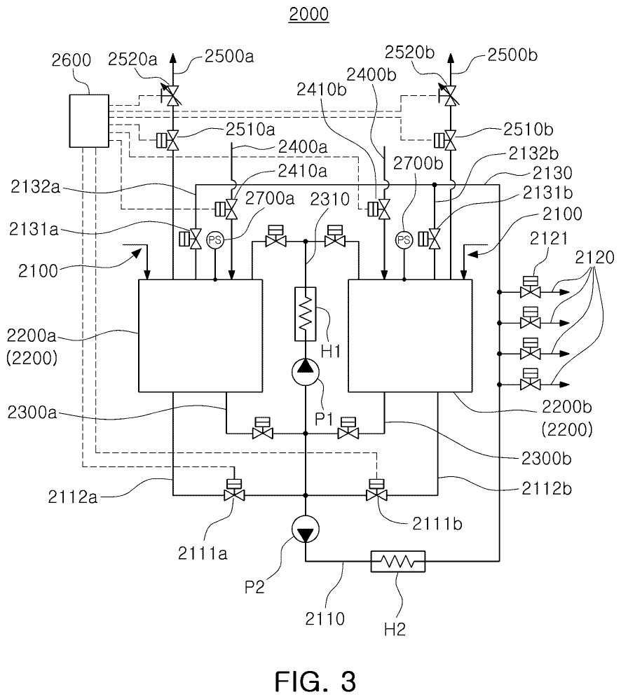

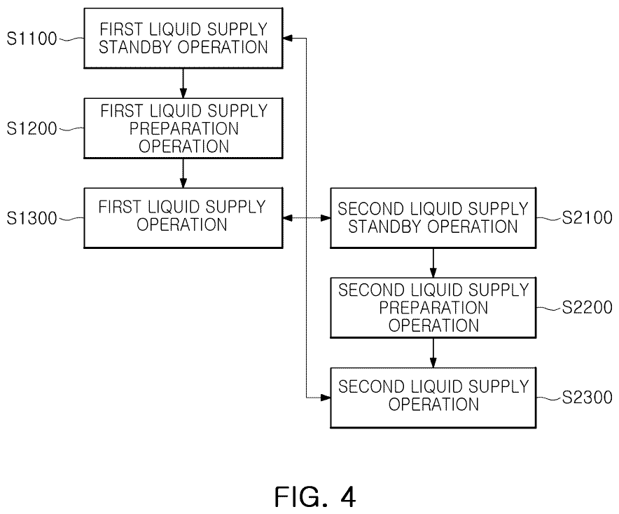

In the description below, an apparatus for processing a substrate and a method of processing a substrate including a first pressure tank and a second pressure tank will be described with reference to FIGS. 3 and 4 as another embodiment.

FIG. 3 is a diagram illustrating an apparatus for processing a substrate according to an embodiment. FIG. 4 is a flowchart illustrating a method of processing a substrate of an apparatus for processing a substrate according to an embodiment.

Referring to FIG. 3, an apparatus 2000 for processing a substrate according to another embodiment may include a liquid supply line 2100, a pressure tank 2200, a circulation line, a pressured gas supply line, an exhaust line and a control unit 2600.

The liquid supply line 2100 may receive liquid from a liquid supply source and may supply various types of liquid to the substrate in the process chamber such that the substrate may be processed. If desired, the liquid supply line 2100 may supply liquid to a substrate in one or a plurality of process chambers. In FIG. 3, the liquid supply line 2100 may supply liquid to the substrate in each process chamber through the plurality of chamber supply line 2120 of the main supply line 2110, which will be described later, but an embodiment thereof is not limited thereto.

The pressure tank 2200 may be configured to be disposed on the liquid supply line 2100 and to store liquid, and if desired, pressured gas may be supplied to the pressure tank 2200 through a pressured gas supply line to be described later, such that the pressure tank 2200 may store liquid in a state in which an internal portion thereof is pressurized with pressured gas.

Specifically, the pressure tank 2200 may include a first pressure tank 2200a and a second pressure tank 2200b. Also, the pressure tank 2200 may include other tanks in addition to the first pressure tank 2200a and the second pressure tank 2200b, but in the embodiment, for ease of description, the embodiment in which the first pressure tank 2200a and the second pressure tank 2200b are included may be described.

The circulation line, the pressured gas supply line, and the exhaust line connected to the first pressure tank 2200a may be referred to as a first circulation line 2300a, a first pressured gas supply line 2400a, and a first exhaust line 2500a, respectively, and the circulation line, the pressured gas supply line, and the exhaust line connected to the second pressure tank 2200a may be referred to as a second circulation line 2300b, a second pressured gas supply line 2400b, and a second exhaust line 2500b, respectively.

The first circulation line 2300a may be connected to the first pressure tank 2200a such that liquid in the first pressure tank 2200a may circulate in the first pressure tank 2200a through the first circulation line 2300a.

The second circulation line 2300b may be connected to the second pressure tank 2200b such that liquid in the second pressure tank 2200b may circulate in the second pressure tank 2200b through the second circulation line 2300b.

Here, a portion of the first circulation line 2300a and a portion of the second circulation line 2300b may be configured as a shared line 2310.

Liquid flowing through the shared line 2310 may flow back into the first pressure tank 2200a through the first circulation line 2300a, or into the second pressure tank 2200b through the second circulation line 2300b. Accordingly, whether the state is a liquid supply state or a liquid supply standby state, liquid in the first pressure tank 2200a may circulate the first pressure tank 2200a through the first circulation line 2300a, or liquid in the second pressure tank 2200b may circulate the second pressure tank 2200b through the second circulation line 2300b.

The shared line 2310 may include a first heating unit H1 and a first pump P1 which may heat liquid circulating the first pressure tank 2200a and the first circulation line 2300a in the first liquid supply standby state in which liquid circulates the first pressure tank 2200a and the first circulation line 2300a, or may heat liquid circulating the second pressure tank 2200b and the second circulation line 2300b in the second liquid supply standby state in which liquid circulate the second pressure tank 2200b and the second circulation line 2300b.

In other words, in this case of the first liquid supply state in which liquid is supplied to the substrate in the process chamber using the first pressure tank 2200a, liquid heated by the first heating unit H1 disposed on the shared line 2310 in the second liquid supply standby state in which liquid circulates the second pressure tank 2200b and the second circulation line 2300b may circulate the second pressure tank 2200b by driving the first pump P1. Similarly, in this case of the second liquid supply state in which liquid is supplied to the substrate in the process chamber using the second pressure tank 2200b, the first liquid supply standby state in which liquid circulates the first pressure tank 2200a and the first circulation line 2300a, liquid heated by the first heating unit H1 disposed on the shared line 2310 may circulate the first pressure tank 2200a by driving the first pump P1.

Here, for ease of description, the liquid supply state in which liquid is supplied to the substrate in the process chamber using the first pressure tank 2200a may be referred to as a first liquid supply state, and the liquid supply state in which liquid is supplied to the substrate in the process chamber using the second pressure tank 2200b may be referred to as a first liquid supply state. Here, in the first liquid supply state of the first pressure tank 2200a, the second pressure tank 2200b may be in a liquid supply standby state before supplying liquid to the substrate in the process chamber, and in this case, an operation of circulating through the second pressure tank 2200b and the second circulation line 2300b may be performed. Similarly, in the second liquid supply state of the second pressure tank 2200b, the first pressure tank 2200a may be in a liquid supply standby state before supplying liquid to the substrate in the process chamber, and in this case, an operation of circulating through the first pressure tank 2200a and the first circulation line 2300a may be performed. The liquid supply standby state of the first pressure tank 2200a may be referred to as the first liquid supply standby state, and the liquid supply standby state of the second pressure tank 2200b may be referred to as the second liquid supply standby state.

The first pressured gas supply line 2400a may be connected to the first pressure tank 2200a and may supply pressured gas to the first pressure tank 2200a. The first pressured gas supply valve 2410a may be disposed on the first pressured gas supply line 2400a, and may control whether pressured gas is supplied from the first pressured gas supply line 2400a into the first pressure tank 2200a and a supply flow rate thereof through the first pressured gas supply valve 2410a. As pressured gas, the first pressured gas supply line 2400a may supply N₂ gas, for example, into the first pressure tank 2200a. By supplying N₂ gas into the first pressure tank 2200a through the first pressured gas supply line 2400a, the gas may work as a purge to prevent gases or contaminants other than liquid from being accommodated in the first pressure tank 2200a.

The first pressured gas supply line 2400a may supply pressured gas to the first pressure tank 2200a in the first liquid supply standby state and may pressurize an internal portion of the first pressure tank 2200a. Specifically, in the first liquid supply standby state, pressured gas may be supplied to the first pressure tank 2200a through the first pressured gas supply line 2400a while the first pressure tank 2200a is sealed, and may pressurize an internal portion of the first pressure tank 2200a.

Similarly, the second pressured gas supply line 2400b may be connected to the second pressure tank 2200b and may supply pressured gas to the second pressure tank 2200b. A second pressured gas supply valve 2410b may be disposed on the second pressured gas supply line 2400b, and may control whether pressured gas is supplied from the second pressured gas supply line 2400b into the second pressure tank 2200b through the second pressured gas supply valve 2410b and a supply flow rate thereof. As pressured gas, the second pressured gas supply line 2400b may supply, for example, N₂ gas into the second pressure tank 2200b. By supplying N₂ gas into the second pressure tank 2200b through the second pressured gas supply line 2400b, the gas may work as a purge to prevent gases or contaminants other than liquid from being accommodated in the second pressure tank 2200b.

The second pressured gas supply line 2400b may supply pressured gas to the second pressure tank 2200b in the second liquid supply standby state and may pressurize an internal portion of the second pressure tank 2200b. Specifically, in the second liquid supply standby state, while the second pressure tank 2200b is sealed, pressured gas may be supplied to the second pressure tank 2200b through the second pressured gas supply line 2400b and may pressurize an internal portion of the second pressure tank 2200b.

The first exhaust line 2500a may be connected to the first pressure tank 2200a and may exhaust gas in the first pressure tank 2200a. That is, in the first liquid supply standby state, the first exhaust line 2500a may be closed such that the first pressure tank 2200a may be in a sealed state.

The second exhaust line 2500b may be connected to the second pressure tank 2200b and may exhaust gas in the second pressure tank 2200b. In other words, the second exhaust line 2500b may be closed in the second liquid supply standby state such that the second pressure tank 2200b may be in a sealed state.

The control unit 2600 may control an operation of each component of the apparatus 2000 for processing a substrate.

When one of the first pressure tank 2200a and the second pressure tank 2200b is in liquid supply state, the control unit 2600 may control the other to be in the liquid supply standby state.

In other words, when the first pressure tank 2200a is controlled to be in the first liquid supply state, the control unit 2600 may control the second pressure tank 2200b to be in the second liquid supply standby state. Also, when the second pressure tank 2200b is controlled to be in the second liquid supply state, the control unit 2600 may control the first pressure tank 2200a to be in the first liquid supply standby state.

Specifically, the control unit 2600 may close the first exhaust line 2500a before liquid circulates the first pressure tank 2200a in the first liquid supply standby state, may open the first pressured gas supply line 2400a in the state in which the first pressure tank 2200a is in a sealed state, and may control pressure in the first pressure tank 2200a to increase to a predetermined pressure.

Also, the control unit 2600 may close the second exhaust line 2500b in the second liquid supply standby state before liquid circulates the second pressure tank 2200b, may open the second pressured gas supply line 2400b while the second pressure tank 2200b is in a sealed state, and may control pressure in the second pressure tank 2200b to increase to predetermined pressure.

In the apparatus 2000 for processing a substrate having the above components, liquid may be heated through the first or second circulation lines 2300a and 2300b in the first or second liquid supply standby state, such that, before circulating through the first or second pressure tanks 2200a and 2200b, as the control unit 2600 controls the first or second exhaust line 2500a and 2500b connected to the first or second pressure tank 2200a and 2200b to close and controls the first or second pressured gas supply line 2400a and 2400b to open, pressure in the first or second pressure tank 2200a and 2200b may be increased by supplying pressured gas in the first or second pressure tank 2200a and 2200b, and as the pressure in the first or second pressure tank 2200a and 2200b increases, a boiling point of the liquid in the first or second pressure tank 2200a and 2200b increases, such that evaporation of the liquid may be prevented, and vaporization of liquid may be reduced. Further, since the first or second exhaust line 2500a and 2500b is in a closed state in the first or second liquid supply standby state, the processing gas from liquid vaporized in the sealed first or second pressure tank 2200a and 2200b may not be discharged to the first or second exhaust line 2500a and 2500b, and may be maintained in the first or second pressure tank 2200a or 2200b, thereby reducing consumption of liquid.

Further, the apparatus 2000 for processing a substrate may include a first pressure measurement unit 2700a disposed in the first pressure tank 2200a and measuring the pressure in the first pressure tank 2200a, and a second pressure measurement unit 2700b disposed in the second pressure tank 2200b and measuring the pressure in the second pressure tank 2200b. The first pressure measurement unit 2700a and the second pressure measurement unit 2700b may include a pressure sensor.

In this case, the control unit 2600 may control an output of the first heating unit H1 such that pressure in the first pressure tank 2200a may be maintained at a predetermined pressure according to a pressure value measured from the first pressure measurement unit 2700a. In the first liquid supply standby state, the output of the first heating unit H1 of the shared line 2310 may be controlled according to the pressure value measured from the first pressure measurement unit 2700a while liquid circulates the first pressure tank 2200a through the first circulation line 2300a such that pressure in the first pressure tank 2200a may be maintained at a predetermined pressure.

Similarly, the control unit 2600 may control an output of the first heating unit H1 such that pressure in the second pressure tank 2200b may be maintained at a predetermined pressure according to the pressure value measured from the second pressure measurement unit 2700b. In the second liquid supply standby state, the output of the first heating unit H1 of the shared line 2310 may be controlled according to the pressure value measured from the second pressure measurement unit 2700b while liquid circulates the second pressure tank 2200b through the second circulation line 2300b such that pressure in the second pressure tank 2200b may be maintained at a predetermined pressure.

Also, the liquid supply line 2100 may include a main supply line 2110 connected to the first pressure tank 2200a and the second pressure tank 2200b and selectively supplying liquid from the first pressure tank 2200a or the second pressure tank 2200b to the substrate in the process chamber. As an example, the main supply line 2110 may include a first branch line 2112a connected to the first pressure tank 2200a and a second branch line 2112b connected to the second pressure tank 2200b, and lower ends of the first branch line 2112a, and the second branch line 2112b may be connected to each other such that the first branch line 2112a, and the second branch line 2112b may be joined to each other. The first supply valve 2111a opening and closing or adjusting a flow of liquid from the first pressure tank 2200a may be disposed on the first branch line 2112a. A second supply valve 2111b opening and closing or adjusting a flow of liquid from the second pressure tank 2200b may be disposed on the second branch line 2112b.

Also, the main supply line 2110 may further include a chamber supply line 2120 and a recovery line 2130.

The chamber supply line 2120 may supply liquid discharged from the first pressure tank 2200a or the second pressure tank 2200b to the substrate in the process chamber. A plurality of the chamber supply lines 2120 may be provided, and a chamber supply valve 2121 may be disposed on each chamber supply line 2120.

The recovery line 2130 may include a first recovery line 2132a recovering liquid discharged from the first pressure tank 2200a back to the first pressure tank 2200a, and a second recovery line 2132b recovering liquid discharged from the second pressure tank 2200b back to the second pressure tank 2200b. When pressure of liquid in the main supply line 2110 is a predetermined pressure or higher, the first recovery line 2132a may not allow liquid to be supplied to the chamber supply line 2120 and may allow liquid to be recovered to the first pressure tank 2200a. The first recovery valve 2131a may be disposed in the first recovery line 2132a, and whether to recover liquid recovered from the main supply line 2110 to the first pressure tank 2200a through the first recovery valve 2131a of the first recovery line 2132a and a recovery flow rate thereof may be adjusted. The second recovery line 2132b may not allow liquid to be supplied to the chamber supply line 2120 and may allow liquid to recover to the second pressure tank 2200b when pressure of liquid in the main supply line 2110 is a predetermined pressure or higher. The second recovery valve 2131b may be disposed in the second recovery line 2132b, and whether to recover liquid recovered from the main supply line 2110 to the second pressure tank 2200b through the second recovery valve 2131b of the second recovery line 2132b and a recovery flow rate thereof may be adjusted.

Further, in a flow direction of liquid, the main supply line 2110 on an upper side of the chamber supply line 2120 and the recovery line 2130 may include a second heating unit H2 for heating liquid and a second pump P2 for pumping liquid. Accordingly, liquid discharged from the first or second pressure tanks 2200a and 2200b may be supplied to the main supply line 2110, may be heated secondarily by the second heating unit H2, and may be supplied to the substrate in the process chamber through the chamber supply line 2120.

Also, when switching from the first liquid supply standby state to the first liquid supply state, to reduce the risk of explosion due to high pressure in the first pressure tank 2200a, the control unit 2600 may control the first exhaust line 2500a to be gradually open before switching from the first liquid supply standby state to the first liquid supply state. To implement this, as an example, a first exhaust open/close valve 2510a and a first relief valve 2520a may be disposed in the first exhaust line 2500a. By including the components, before switching from the first liquid supply standby state to the first liquid supply state, the control unit 2600 may control the first exhaust open/close valve 2510a and the first relief valve 2520a to open, such that pressure in the first pressure tank 2200a may be gradually released through the first exhaust line 2500a, and accordingly, when switching from the first liquid supply standby state to the first liquid supply state, explosion due to sudden pressure changes may be effectively prevented.

Similarly, when switching from the second liquid supply standby state to the second liquid supply state, to reduce the risk of explosion due to high pressure in the second pressure tank 2200b, the control unit 2600 may control the second exhaust line 2500b to be gradually open before switching from the second liquid supply standby state to the second liquid supply state. To implement this, as an example, a second exhaust open/close valve 2510b and a second relief valve 2520b may be disposed in the second exhaust line 2500b. By including the components, before switching from the second liquid supply standby state to the second liquid supply state, the control unit 2600 may control the second exhaust open/close valve 2510b and the second relief valve 2520b to open, such that pressure in the second pressure tank 2200b may be gradually released through the second exhaust line 2500b, and accordingly, when switching from the second liquid supply standby state to the second liquid supply state, explosion due to sudden pressure changes may be effectively prevented.

According to another embodiment, a method of processing a substrate using the apparatus 2000 for processing a substrate may be provided.

The method of processing a substrate of apparatus 2000 for processing a substrate according to another embodiment may include processing a substrate in a process chamber using a first pressure tank 2200a and a second pressure tank 2200b disposed in parallel with each other on a liquid supply line 2100 for supplying liquid.

A first circulation line 2300a in which liquid stored therein circulates while being heated and a first exhaust line 2500a which exhausts gas in the first pressure tank 2200a may be connected to the first pressure tank 2200a. Also, as described above, the first pressured gas supply line 2400a for supplying pressured gas into the first pressure tank 2200a may be connected to the first pressure tank 2200a, and the first branch line 2112a of the main supply line 2110 among the liquid supply lines 2100 may be connected to the first pressure tank 2200a.

A second circulation line 2300b in which liquid stored therein circulates while being heated, and a second exhaust line 2500b which exhausts gas in the second pressure tank 2200b may be connected to the second pressure tank 2200b. Also, as described above, the second pressured gas supply line 2400b for supplying pressured gas into the second pressure tank 2200b may be connected to the second pressure tank 2200b, and the second branch line 2112b of the main supply line 2110 of the liquid supply line 2100 may be connected to the second pressure tank 2200b.

The method of processing a substrate of the apparatus 2000 for processing a substrate may include a first liquid supply standby operation (S1100), a first liquid supply preparation operation (S1200), a first liquid supply operation (S1300), a second liquid supply standby operation (S2100), a second liquid supply preparation operation (S2200) and a second liquid supply operation (S2300).

In the first liquid supply standby operation (S1100), pressured gas may be supplied to the sealed first pressure tank 2200a by closing the first exhaust line 2500a, and may be pressurized, liquid in the first pressure tank 2200a may circulate through the first pressure tank 2200a while being heated through the first circulation line 2300a. In the first liquid supply standby operation (S1100), pressured gas may be supplied to the first pressure tank 2200a by opening the first pressured gas supply valve 2410a of the first pressured gas supply line 2400a connected to the first pressure tank 2200a. Here, as an example, as pressured gas, N₂ gas may be supplied to the first pressure tank 2200a and may be pressurized. Also, in the first liquid supply standby operation (S1100), liquid circulating the first circulation line 2300a may be heated by the first heating unit H1 disposed on the shared line 2310 including a portion of the first circulation line 2300a and a portion of the second circulation line 2300b.

In the second liquid supply standby operation (S2100), pressured gas may be supplied to the sealed second pressure tank 2200b by closing the second exhaust line 2500b and may be pressurized, and liquid in the second pressure tank 2200b may circulate in the second pressure tank 2200b while being heated through the second circulation line 2300b. In the second liquid supply standby operation (S2100), pressured gas may be supplied to the second pressure tank 2200b by opening the second pressured gas supply valve 2410b of the second pressured gas supply line 2400b connected to the second pressure tank 2200b. Here, as an example, as pressured gas, N₂ gas may be supplied to the second pressure tank 2200b and may be pressurized. Also, in the second liquid supply standby operation (S2100), liquid circulating the second circulation line 2300b may be heated by the first heating unit H1 disposed on the shared line 2310 including a portion of the first circulation line 2300a and a portion of the second circulation line 2300b.

In the first liquid supply operation (S1300), liquid may be supplied to the substrate in the process chamber through the first pressure tank 2200a. That is, liquid discharged from the first pressure tank 2200a in the first liquid supply operation (S1300) may be supplied to the substrate in the process chamber through the chamber supply line 2120 of the main supply line 2110 to process the substrate.

In the second liquid supply operation (S2300), liquid may be supplied to the substrate in the process chamber through the second pressure tank 2200b. That is, liquid discharged from the second pressure tank 2200b in the second liquid supply operation (S2300) may be supplied to the substrate in the process chamber through the chamber supply line 2120 of the main supply line 2110 to process the substrate.

The first liquid supply operation (S1300) and the second liquid supply standby operation (S2100) may be performed simultaneously. The second liquid supply operation (S2300) and the first liquid supply standby operation (S1100) may be performed simultaneously. In other words, when the first liquid supply operation (S1300) is performed to supply liquid to the substrate in the process chamber using the first pressure tank 2200a, the second liquid supply standby operation (S2100) may also be performed simultaneously such that an operation in which liquid in the second pressure tank 2200b circulates the second pressure tank 2200b through the second circulation line 2300b may be performed. Similarly, when performing the second liquid supply operation (S2300) to supply liquid to the substrate in the process chamber using the second pressure tank 2200b, the first liquid supply standby operation (S1100) may be performed such that an operation in which liquid in the first pressure tank 2200a circulates the first pressure tank 2200a through the first circulation line 2300a may be performed.

Also, in the first liquid supply standby operation (S1100), an output of the first heating unit H1 for heating liquid circulating the first pressure tank 2200a may be controlled to maintain pressure in the first pressure tank 2200a at a predetermined pressure. Specifically, in the first liquid supply standby operation (S1100), by measuring a pressure value in the first pressure tank 2200a, the output of the first heating unit H1 may be controlled such that pressure in the first pressure tank 2200a may be maintained at a predetermined pressure according to the measured pressure value.

In the second liquid supply standby operation (S2100), the output of the first heating unit H1 for heating liquid circulating the second pressure tank 2200b may be controlled such that pressure in the second pressure tank 2200b may be maintained at a predetermined pressure. Specifically, in the second liquid supply standby operation (S2100), by measuring the pressure value in the second pressure tank 2200b, the output of the first heating unit H1 may be controlled such that pressure in the first pressure tank 2200b may be maintained at a predetermined pressure according to the measured pressure value.

Also, when switching from the first liquid supply standby operation (S1100) to the first liquid supply operation (S1300) or from the second liquid supply standby operation (S2100) to the second liquid supply operation (S2300), there may be a risk of explosion due to high pressure in the first pressure tank 2200a or the second pressure tank 2200b, and to present this, the first liquid supply preparation operation (S1200) or the second liquid supply preparation operation (S2200) may be performed.

In the first liquid supply preparation operation (S1200), the first exhaust line 2500a may be opened gradually after the first liquid supply standby operation (S1100) and before the first liquid supply operation (S1300). In the first liquid supply preparation operation (S1200), the first exhaust open/close valve 2510a and the first relief valve 2520a disposed on the first exhaust line 2500a may be open, and accordingly, pressure in the first pressure tank 2200a may be gradually released, such that, when the first liquid supply operation (S1300) is performed, explosion due to sudden pressure changes in the first pressure tank 2200a may be effectively prevented.

Further, in the first liquid supply operation (S1300), the first exhaust open/close valve 2510a and the first relief valve 2520a may be maintained in an open state. Also, in the first liquid supply standby operation (S1100), the first pressure tank 2200a may be in a sealed state by closing the first exhaust open/close valve 2510a and the first relief valve 2520a.

In the second liquid supply preparation operation (S2200), the second exhaust line 2500b may be opened gradually after the second liquid supply standby operation (S2100) and before the second liquid supply operation (S2300) In the second liquid supply preparation operation (S2200), the second exhaust open/close valve 2510b and the second relief valve 2520b disposed on the second exhaust line 2500b may be open, and accordingly, pressure in the second pressure tank 2200b may be gradually released such that, when the second liquid supply operation (S2300) is performed, explosion due to sudden pressure changes in the second pressure tank 2200b may be effectively prevented.

Further, in the second liquid supply operation (S2300), the second exhaust open/close valve 2510b and the second relief valve 2520b may be maintained in an open state. Also, in the second liquid supply standby operation (S2100), the second pressure tank 2200b may be in a sealed state by closing the second exhaust open/close valve 2510b and the second relief valve 2520b.

In the above embodiment, the first and second exhaust open/close valves 2510a and 2510b and the first and second relief valves 2520a and 2520b may be disposed as components for gradually opening the first and second exhaust lines 2500a and 2500b, but an embodiment thereof is not limited thereto, and any components which may gradually open the first and second exhaust lines may be applied, and as another example, a control valve for controlling an exhaust flow rate of the first and second exhaust lines may be applied.

According to the method of processing a substrate, liquid may be heated through the first or second circulation lines 2300a and 2300b in the first or second liquid supply standby operation (S1100) and before circulating the first or second pressure tank 2200a and 2200b, the control unit 2600 may close the first or second exhaust line 2500a and 2500b connected to the first or second pressure tank 2200a and 2200b, and by supplying pressured gas in the sealed first or second pressure tank 2200a and 2200b, pressure in the first or second pressure tank 2200a and 2200b may be increased, and as the pressure in the first or second pressure tank 2200a and 2200b increases, a boiling point of the liquid in the first or second pressure tank 2200a and 2200b may increase, such that vaporization of liquid may be reduced. Further, in the first or second liquid supply standby operation (S1100) and S2100, the first or second exhaust line 2500a and 2500b may be in a closed state, such that the processing gas from liquid vaporized in the sealed first or second pressure tank 2200a and 2200b may not be discharged to the second exhaust line 2500a and 2500b, and may be maintained in the first or second pressure tank 2200a and 2200b, thereby reducing consumption of liquid.

According to the aforementioned embodiments, in the apparatus for processing a substrate and the method of processing a substrate, in the liquid supply standby state, as liquid is heated through the circulation line, before circulating the pressure tank, the control unit may control the exhaust line connected to the pressure tank to close and may control the pressured gas supply line to open in a state in which the pressure tank is sealed, such that pressured gas may be supplied to the sealed pressure tank to increase pressure in the pressure tank, and accordingly, as pressure in the pressure tank increases, a boiling point of the liquid may increase, such that evaporation of liquid may be prevented, thereby reducing vaporization of liquid. Further, since the exhaust line is in a closed state, the processing gas from liquid vaporized in the sealed pressure tank may not be discharged to the exhaust line and may be maintained in the pressure tank, thereby reducing consumption of liquid. While the embodiments have been illustrated and described above, it will be apparent to those skilled in the art that modifications and variations could be made without departing from the scope of the present disclosure as defined by the appended claims.

What is claimed is:

1. An apparatus for processing a substrate, the apparatus comprising:
a liquid supply line configured to supply liquid;
a pressure tank disposed on the liquid supply line and configured to store liquid;
a circulation line including a first heating unit configured to heat liquid disposed therein and connected to the pressure tank, wherein liquid heated by the first heating unit circulates in the pressure tank in a liquid supply standby state, which is before liquid is supplied to the substrate in a process chamber;
a pressured gas supply line connected to the pressure tank and configured to supply pressured gas to the pressure tank in the liquid supply standby state and to pressurize gas;
an exhaust line connected to the pressure tank and configured to exhaust gas in the pressure tank; and
a control unit configured to control pressure in the pressure tank to increase to a predetermined pressure by opening the pressured gas supply line in a state in which the pressure tank is closed by closing the exhaust line before liquid circulates in the pressure tank in the liquid supply standby state.

2. The apparatus of claim 1, wherein
wherein the liquid supply line includes a main supply line connected to one of the pressure tank and the circulation line and configured to supply liquid from the pressure tank to the substrate in the process chamber, and
wherein the control unit controls the exhaust line to open before switching from a liquid supply standby state to a liquid supply state in which liquid is supplied to the substrate in the process chamber through the main supply line.

3. The apparatus of claim 2, wherein an exhaust open/close valve and a relief valve are disposed in the exhaust line.

4. The apparatus of claim 2,
wherein the main supply line is connected to the pressure tank, and
wherein the apparatus further includes:
a chamber supply line configured to supply liquid discharged from the pressure tank to the substrate in the process chamber; and
a recovery line configured to recover liquid discharged from the pressure tank back to the pressure tank.

5. The apparatus of claim 4, wherein the main supply line disposed on an upper side of the chamber supply line and the recovery line includes a second heating unit configured to heat liquid.

6. The apparatus of claim 1, further comprising:
a pressure measurement unit configured to measure pressure in the pressure tank,
wherein the control unit controls an output of the first heating unit to maintain pressure in the pressure tank at a predetermined pressure according to a pressure value measured from the pressure measurement unit.

7. The apparatus of claim 1,
wherein the pressure tank includes at least a first pressure tank and a second pressure tank, and
wherein, when one of the first pressure tank and the second pressure tank is in liquid supply state, the other is controlled to be in the liquid supply standby state.

8. A method of processing a substrate using a pressure tank disposed on a liquid supply line configured to supply liquid and connected to a circulation line in which liquid stored therein circulates while being heated and an exhaust line, the method comprising:
a liquid supply standby operation in which, by closing the exhaust line, pressured gas is supplied to the sealed pressure tank and is pressurized, and liquid in the pressure tank circulates in the pressure tank while being heated through the circulation line; and
a liquid supply operation in which liquid is supplied to a substrate in a process chamber through the pressure tank.

9. The method of claim 8, wherein the method further includes a liquid supply preparation operation in which the exhaust line is gradually opened after the liquid supply standby operation and before the liquid supply operation.

10. The method of claim 9, wherein an exhaust open/close valve and a relief valve disposed on the exhaust line are opened in the liquid supply preparation operation, the exhaust open/close valve and the relief valve are maintained in an open state in the liquid supply operation, and the exhaust open/close valve and the relief valve are closed in the liquid supply standby operation.

11. The method of claim 8, wherein, in the liquid supply standby operation, an output of a heating unit configured to heat liquid circulating in the pressure tank is controlled such that pressure in the pressure tank is maintained at a predetermined pressure.

12. A method of processing a substrate using a first pressure tank disposed on a liquid supply line configured to supply liquid and connected to a first circulation line in which liquid stored therein circulates while being heated and a first exhaust line; and a second pressure tank disposed in parallel to the first pressure tank on the supply line and connected to a second circulation line in which liquid stored therein circulates while being heated and a second exhaust line, the method comprising:
a first liquid supply standby operation in which, by closing the first exhaust line, pressured gas is supplied to the sealed first pressure tank and is pressurized, and liquid in the first pressure tank circulates the first pressure tank while being heated through the first circulation line;
a second liquid supply standby operation in which, by closing second exhaust line, pressured gas is supplied to the sealed second pressure tank and is pressurized, and liquid in the second pressure tank circulates the second pressure tank while being heated through the second circulation line;
a first liquid supply operation in which liquid is supplied to the substrate in the process chamber through the first pressure tank; and
a second liquid supply operation in which liquid is supplied to the substrate in the process chamber through the second pressure tank,
wherein the first liquid supply operation and the second liquid supply standby operation are performed simultaneously, and
wherein the second liquid supply operation and the first liquid supply standby operation are performed simultaneously.

13. The method of claim 12, wherein the method further includes a first liquid supply preparation operation in which the first exhaust line is gradually opened after the first liquid supply standby operation and before the first liquid supply operation.

14. The method of claim 13, wherein a first exhaust open/close valve and a first relief valve disposed on the first exhaust line are opened in the first liquid supply preparation operation.

15. The method of claim 12, wherein, in the first liquid supply standby operation, an output of the heating unit configured to heat liquid circulating the first pressure tank is controlled such that pressure in the first pressure tank is maintained at a predetermined pressure.

16. The method of claim 12, wherein the method further includes a second liquid supply preparation operation in which the second exhaust line is gradually opened after the second liquid supply standby operation and before the second liquid supply operation.

17. The method of claim 16, wherein a second exhaust open/close valve and a second relief valve disposed on the second exhaust line are opened in the second liquid supply preparation operation.

18. The method of claim 12, wherein, in the second liquid supply standby operation, an output of the heating unit configured to heat liquid circulating the second pressure tank is controlled such that pressure in the second pressure tank is maintained at a predetermined pressure.

19. The method of claim 15, wherein a portion of the first circulation line and a portion of the second circulation line are configured as a shared line, and in the first liquid supply standby operation or the second liquid supply standby operation, liquid circulating the first circulation line or the second circulation line is heated by a heating unit disposed in the shared line.

20. The method of claim 12,
wherein the method further includes a first liquid supply preparation operation in which the first exhaust line is gradually opened after the first liquid supply standby operation and before the first liquid supply operation,
wherein the method further includes a second liquid supply preparation operation in which the second exhaust line is gradually opened after the second liquid supply standby operation and before the second liquid supply operation,
wherein a first exhaust open/close valve and a first relief valve disposed on the first exhaust line are opened in the first liquid supply preparation operation, the first exhaust open/close valve and the first relief valve are maintained in an open state in the first liquid supply operation, and the first exhaust open/close valve and the first relief valve are closed in the first liquid supply standby operation, and
wherein the second exhaust open/close valve and the second relief valve disposed on the second exhaust line are opened in the second liquid supply preparation operation, the second exhaust open/close valve and the second relief valve are maintained in an open state in the second liquid supply operation, and the second exhaust open/close valve and the second relief valve are closed in the second liquid supply standby operation.
